(19) United States
(12) Patent Application Publication
(10) Pub. No.: US 2024/0312942 A1
(43) Pub. Date: Sep. 19, 2024

(54) REFLECTIVE INORGANIC THIN FILM FOR HIGH-DENSITY PANEL-SCALE RE-DISTRIBUTION LAYER (RDL)

(71) Applicant: Intel Corporation, Santa Clara, CA (US)

(72) Inventors: Vidya JAYARAM, Chandler, AZ (US); Karan BHANGAONKAR, Chandler, AZ (US); Chandrasekharan NAIR, Mesa, AZ (US)

(21) Appl. No.: 18/120,904

(22) Filed: Mar. 13, 2023

(51) Int. Cl. H01L 23/00; H01L 21/311; H01L 23/498; H01L 23/522

(52) U.S. Cl. CPC H01L 24/19; H01L 21/31116; H01L 23/49816; H01L 23/5226; H01L 24/16; H01L 2224/16012; H01L 2224/19

(57) ABSTRACT

Embodiments disclosed herein include package substrates. In an embodiment, the package substrate comprises a layer with a film over the layer. In an embodiment, the film is an inorganic material. In an embodiment, the package substrate may further comprise a plurality of electrically conductive traces over the film, and a seed layer between the plurality of electrically conductive traces and the film. In an embodiment, edges of the seed layer are substantially aligned with edges of the plurality of electrically conductive traces.

### TECHNICAL FIELD

Embodiments of the present disclosure relate to electronic packages, and more particularly to packaging architectures that include high-density routing with a thin inorganic film for improved patterning.

### BACKGROUND

High-yield, high-density panel-scale redistribution layers (RDLs) are not manufacturable with current process flows. One challenge is the fabrication of fine pitch (i.e., small line/space (L/S)) copper traces on polymer dielectric layers due to sidewall etching and undercut during wet chemical etching processes. Additionally, fabrication of small diameter micro-vias with small via landing pads is limited by current laser drilling technology. For example, currently available minimum dimensions are 15 μm diameter vias with 30 μm landing pads.

Etching chemistries with high selectivity for etching copper seed layer over the electrolytic plated copper do exist. However, sidewall etching can only be minimized to a certain extent. As such, there is still a high risk of undercut. This can lead to delamination of the fine trace width features in the RDL. Additionally, smaller via diameters may be formed with different drilling solutions, such as excimer laser or via patterning with photo-sensitive dielectrics. Excimer lasers are a high-cost solution and suffer from low throughput. Via patterning using photo-sensitive dielectrics suffer from reliability issues, such as delamination and cracking. Photo-sensitive dielectrics also suffer from poor mechanical properties (e.g., poor adhesion, high coefficient of thermal expansion (CTE), high moisture absorption, and the like).

### BRIEF DESCRIPTION OF THE DRAWINGS

FIG. 1 is a cross-sectional illustration of a package substrate with pads that are exposed with a laser drilling process, in accordance with an embodiment .

FIG. 2 is a cross-sectional illustration of a package substrate with traces where the seed layer between traces is removed with a laser ablation process that damages the underlying substrate, in accordance with an embodiment.

FIG. 3 is a cross-sectional illustration of a package substrate with conductive features that are provided over a seed layer that has been etched with an isotropic etching process that undercuts the conductive features, in accordance with an embodiment.

FIG. 4 is a cross-sectional illustration of a package substrate with a patterned thin film to form openings through the package substrate with a diameter that is smaller than the spot size of the laser, in accordance with an embodiment.

FIG. 5A is a cross-sectional illustration of a package substrate with conductive features over a seed layer and a film, in accordance with an embodiment.

FIG. 5B is a cross-sectional illustration of the package substrate after the seed layer is removed from over the film with a laser ablation process, in accordance with an embodiment.

FIG. 6A is a cross-sectional illustration of a package substrate with conductive features over a first dielectric layer and surrounded by a second dielectric layer, in accordance with an embodiment.

FIG. 6B is a cross-sectional illustration of the package substrate after a film is disposed over the second dielectric layer, in accordance with an embodiment.

FIG. 6C is a cross-sectional illustration of the package substrate after a photoresist material is disposed over the film, in accordance with an embodiment.

FIG. 6D is a cross-sectional illustration of the package substrate after an opening is patterned into the photoresist material, in accordance with an embodiment.

FIG. 6E is a cross-sectional illustration of the package substrate after the opening equal to the target via diameter is transferred into the film, in accordance with an embodiment.

FIG. 6F is a cross-sectional illustration of the package substrate after the photoresist is removed, in accordance with an embodiment.

FIG. 6G is a cross-sectional illustration of the package substrate after a via opening through the patterned film is formed using the patterned film as a hardmask, in accordance with an embodiment.

FIG. 6H is a cross-sectional illustration of the package substrate after a seed layer is deposited, in accordance with an embodiment.

FIG. 6I is a cross-sectional illustration of the package substrate after conductive features are formed over the seed layer, in accordance with an embodiment.

FIG. 6J is a cross-sectional illustration of the package substrate after the seed layer is removed with a laser, in accordance with an embodiment.

FIG. 7 is a cross-sectional illustration of a computing system that includes a package substrate with conductive features over a film, in accordance with an embodiment.

FIG. 8 is a schematic of a computing device built in accordance with an embodiment.

### EMBODIMENTS OF THE PRESENT DISCLOSURE

Described herein are packaging architectures that include high-density routing with a thin reflective inorganic film for improved patterning, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, high density routing on redistribution layers (RDLs) are limited in existing manufacturing techniques. For example, via diameters (which affect minimum pad diameters) are limited by the spot size of the lasers used to drill the via openings. Additionally, when lasers are used to remove the seed layers, the underlying dielectric material may be damaged, which can negatively impact device reliability. Alternatively, if an etching process (e.g., an isotropic wet etching process) is used, then the seed layer below the conductive features may be undercut and result in delamination.

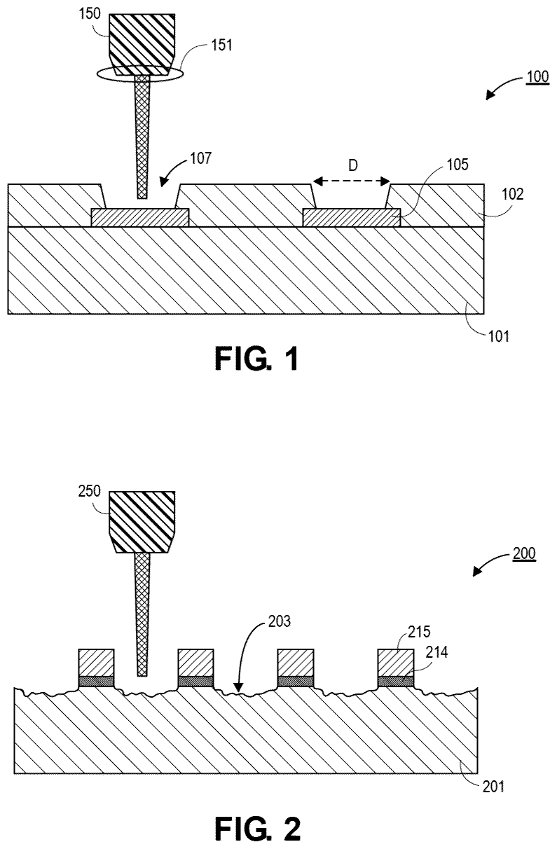

Referring now to FIG. 1, a cross-sectional illustration of a portion of a package substrate 100 is shown. The package substrate 100 may comprise a first layer 101 and a second layer 102 over the first layer 101. The first layer 101 and the second layer 102 may be dielectric materials. For example, the first layer 101 and the second layer 102 may comprise a buildup film or the like. In an embodiment, the first layer 101 and the second layer 102 may comprise the same material. The package substrate 100 may be part of an RDL in some embodiments.

In some instances, electrically conductive pads 105 may be provided between the first layer 101 and the second layer 102. The electrically conductive pads 105 may comprise copper. Barrier layers, seed layers, and the like may also be provided below the pads 105. As shown, via openings 107 are provided through the second layer 102 in order to expose a portion of the pads 105. For example, the via openings 107 may be formed with laser ablation from a laser 150. The diameter D of the via opening 107 is limited by the spot size 151 of the laser 150. With typical laser processes, the spot size 151 is limited to between approximately 10 μm and approximately 15 μm. As used herein, “approximately” may refer to a range of values within ten percent of the stated value. For example, approximately 10 μm may refer to a range between 9 μm and 11 μm. The relatively large spot size 151 results in the diameter of the pad 105 being large as well (e.g., approximately 30 μm or larger).

Referring now to FIG. 2, a cross-sectional illustration of a portion of a package substrate 200 is shown. As shown, a plurality of conductive traces 215 may be provided over a layer 201, such as a dielectric layer 201. The conductive traces 215 may be plated up (e.g., using electrolytic plating) from a seed layer 214. Initially, the seed layer 214 extends over an entire top surface of the layer 201. In order to electrically isolate the conductive traces 215 from each other, a laser 250 is used to ablate the seed layer 214, as shown in FIG. 2.

However, the laser ablation process may negatively impact the surface 203 of the layer 201. For example, due to non-uniform seed layer 214 thickness, the laser ablation process may continue into the top surface 203. As such, the surface 203 may have a non-planar, jagged, profile. Such surfaces negatively impact the reliability of the package substrate 200. For example, the non-planar surface may negatively impact adhesion, layer thickness uniformity, and other design parameters. Accordingly, it may not be desirable to use a laser ablation process in order to remove the seed layer 214. However, as will be described below, other options have negative aspects as well.

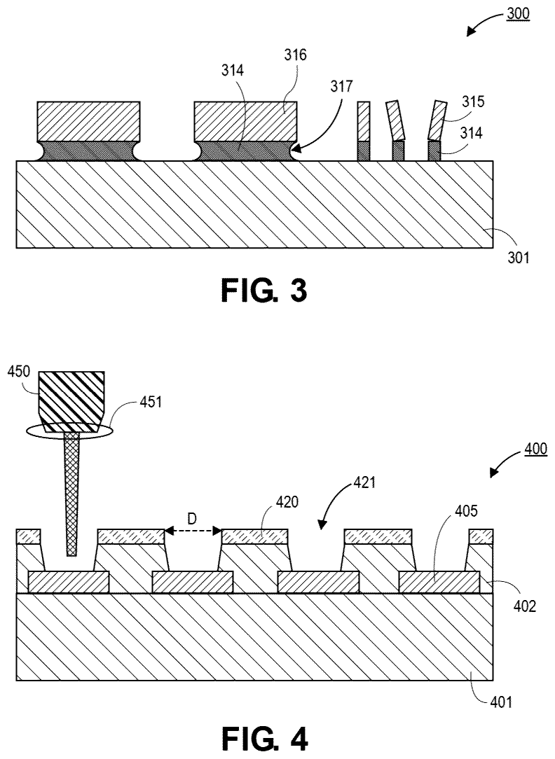

Referring now to FIG. 3, a cross-sectional illustration of a portion of a package substrate 300 is shown. The package substrate 300 may comprise a layer 301, such as a dielectric layer. Conductive features (e.g., pads 316 and traces 315) may be provided over the top surface of the layer 301. In some instances, the conductive features may be plated up from a seed layer 314. The seed layer 314 extends across the entire top surface of the layer 301, and an etching process may be used to remove the seed layer 314 from between pads 316 and/or traces 315.

The etching process may be an isotropic etching process. Due to the isotropic nature of the etch, the regions of the seed layer 314 below the conductive features may be undercut. For example, surfaces 317 may be recessed from an edge of the conductive feature, such as the pad 316. The traces 315 may also suffer from an undercut in the seed layer 314. The presence of an undercut negatively impacts device reliability. For example, as shown in FIG. 3, the traces 315 may lift off from the underlying layer 301. Pads 316 may also lift off or delaminate in some instances.

Accordingly, existing processes do not allow for a desired level of optimization with respect to feature size and product reliability when laser etching and/or isotropic etching is used to form the RDL. As such, embodiments disclosed herein include package substrate architectures that further comprise a film between the seed layer and the underlying dielectric layer. The film may be an inorganic film material, such as an oxide (e.g., comprising silicon and oxygen) or a carbide (e.g., comprising silicon and carbon). The film may also be a mixture of elements such as an oxynitride (e.g., Si—O—N), or an oxycarbide (e.g., Si—O—C). The film may also be a reflective material in order to prevent absorption of the laser used for ablating processes. In an embodiment, the composition of the film may be adjusted to provide optimum reflectivity for the wavelength of the laser chosen.

The use of such a film has several advantages. A first advantage is that the film can be used as a hardmask during laser via opening operations. For example, a hole with a diameter smaller than the spot size of the laser can be formed through the film (e.g., with a lithography process). The film acts as a hardmask that allows for smaller diameter via openings to be formed. For example, via opening diameters may be approximately 5 μm or less, or between approximately 1um and approximately 3 μm. As such the underlying pads may also be reduced in dimension. This allows for higher density routing.

Another advantage is that the film serves as a protective layer between the seed layer and the underlying dielectric layer. This allows for a laser ablation process to be used to remove the seed layer from selected locations without damaging the surface of the underlying dielectric layer. In some instances, the line/spacing (L/S) of traces formed with such processes may be approximately 3 μm/3 μm or less. As such, high density routing is provided. Further, since a laser ablation process is used, the seed layer under the traces does not experience undercutting, and reliability of the package substrate is improved.

Referring now to FIG. 4, a cross-sectional illustration of a portion of a package substrate 400 is shown, in accordance with an embodiment. In an embodiment, the package substrate 400 comprises a first layer 401 and a second layer 402. The first layer 401 and the second layer 402 may comprise a dielectric material, such as a buildup film or the like. In an embodiment, one or more pads 405 may be provided above the first layer 401 and covered by the second layer 402. The pads 405 may be copper pads 405, or any other suitable electrically conductive material. The pads 405 may include barrier layers, seed layers, and the like (not shown) in some embodiments.

In an embodiment, a film 420 is provided over the second layer 402. The film 420 may comprise an inorganic material. In one embodiment, the film 420 comprises an oxide, such as an oxide comprising oxygen and silicon. In other embodiments, the film 420 may comprise a carbide, a nitride, an oxynitride, an oxycarbide, or the like. In an embodiment, the film 420 may have a thickness up to approximately 5 μm thick. In a particular embodiment, the film 420 has a thickness that is between approximately 100 nm and approximately 3 μm. The film 420 may also be considered a reflective film. As used herein, a “reflective film” may refer to a material layer that reflects or otherwise does not absorb the electromagnetic radiation of a laser used to pattern the package substrate.

In an embodiment, the film 420 may have one or more openings 421 over the pads 405. The openings 421 through the film 420 may be formed with a photolithography process, as will be described in greater detail below. In an embodiment, the diameter D of the openings 421 may be smaller than a spot size 451 of a laser 450. In some embodiments, the diameter D may be approximately 5 μm or less, or approximately 3 μm or less. As such, when the laser 450 is exposed through the openings 421, via openings with reduced diameters are formed in the second layer 402 to expose the pads 405. The portions of the laser exposure that falls outside of the openings 421 is reflected away without patterning the second layer 402.

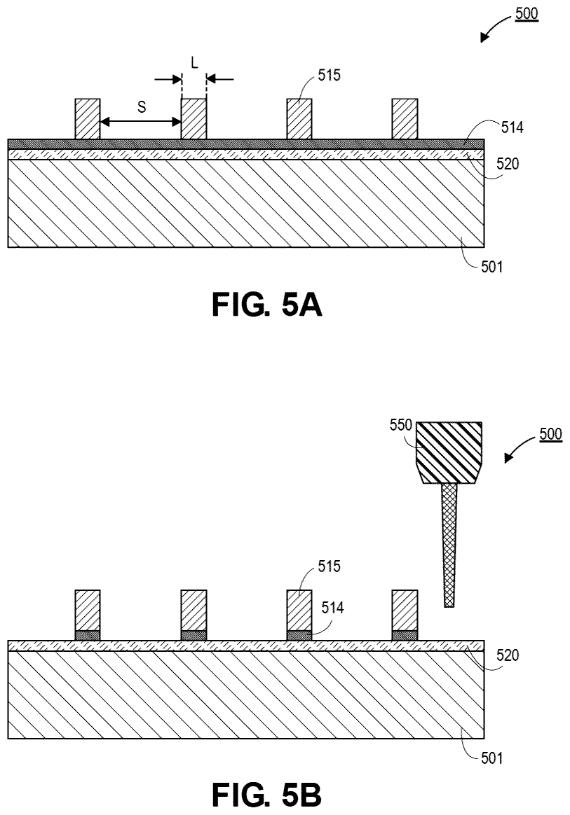

Referring now to FIG. 5A, a cross-sectional illustration of a portion of a package substrate 500 is shown, in accordance with an embodiment. In an embodiment, the package substrate 500 may comprise a first layer 501. The first layer 501 may be a dielectric material, such as a buildup film or the like. In an embodiment, a film 520 is provided over the top surface of the first layer 501. The film 520 may comprise an inorganic material. In one embodiment, the film 520 comprises an oxide, such as an oxide comprising oxygen and silicon. In other embodiments, the film 520 may comprise a carbide. In an embodiment, the film 520 may have a thickness up to approximately 5 μm thick. In a particular embodiment, the film 520 has a thickness that is between approximately 100 nm and approximately 3 μm. The film 520 may also be considered a reflective film.

In an embodiment, a seed layer 514 is provided over the film 520. The seed layer 514 may comprise any standard seed layer formulation. For example, the seed layer 514 may comprise titanium and copper. The seed layer 514 may have a thickness that is between approximately 10 nm and approximately 500 nm. In an embodiment, conductive features, such as traces 515 may be provided over the seed layer 514. The traces 515 may be formed with a plating process, such as an electrolytic plating process. For example, a semi-additive patterning (SAP) process may be used to form the traces 515. For example, the traces 515 may comprise copper. In an embodiment, the traces 515 may have a high-density L/S dimension. For example, the L/S dimension of the traces 515 may be approximately 5 μm/5 μm or less, or approximately 3 μm/3 μm or less.

Referring now to FIG. 5B, a cross-sectional illustration of the package substrate 500 after a seed layer 514 removal process is shown, in accordance with an embodiment. In an embodiment, the seed layer 514 may be removed with a laser ablation process. For example, a laser 550 may be used in order to remove exposed portions of the seed layer 514. Since the laser ablation process is an anisotropic process, the sidewalls of the seed layer 514 below each trace 515 may be substantially vertical and aligned with the sidewalls of the traces 515. Further, since the film 520 is provided below the seed layer 514, the underlying first layer 501 is protected, even when the seed layer 514 has a non-uniform thickness across the surface of the package substrate 500.

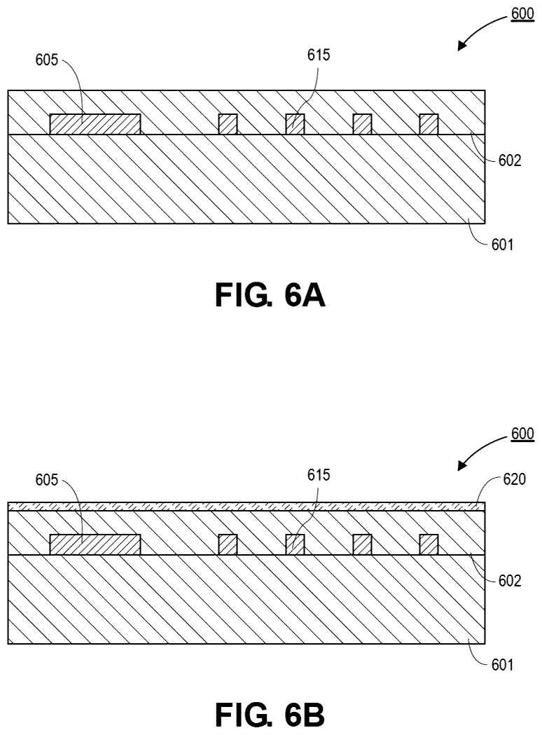

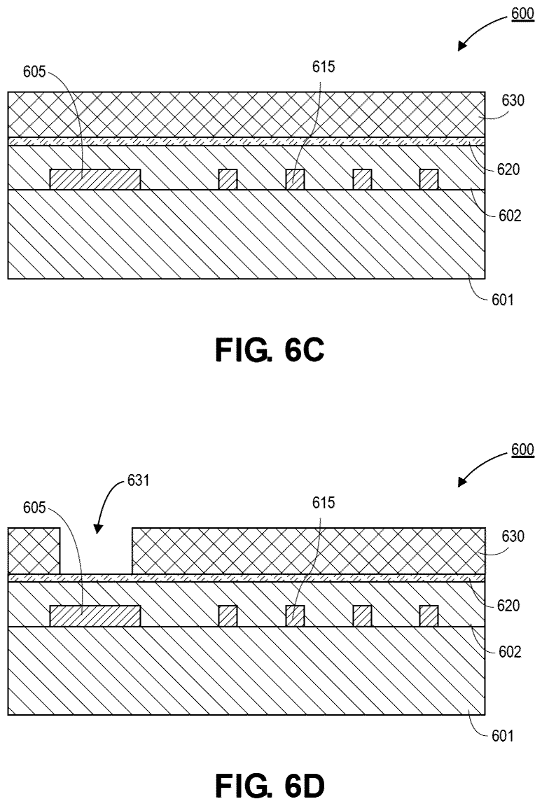

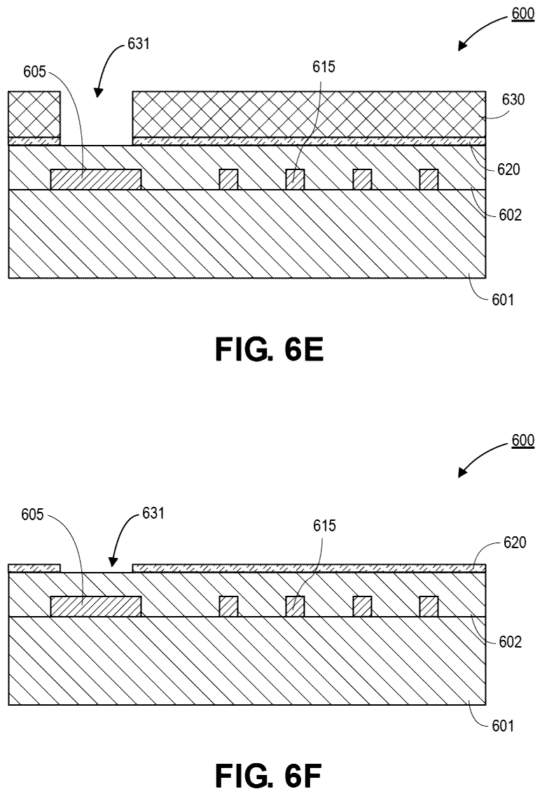

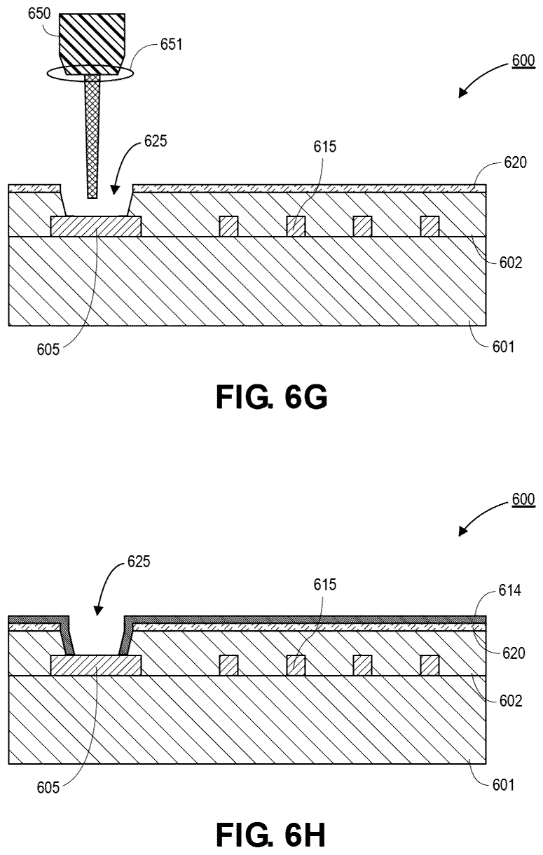

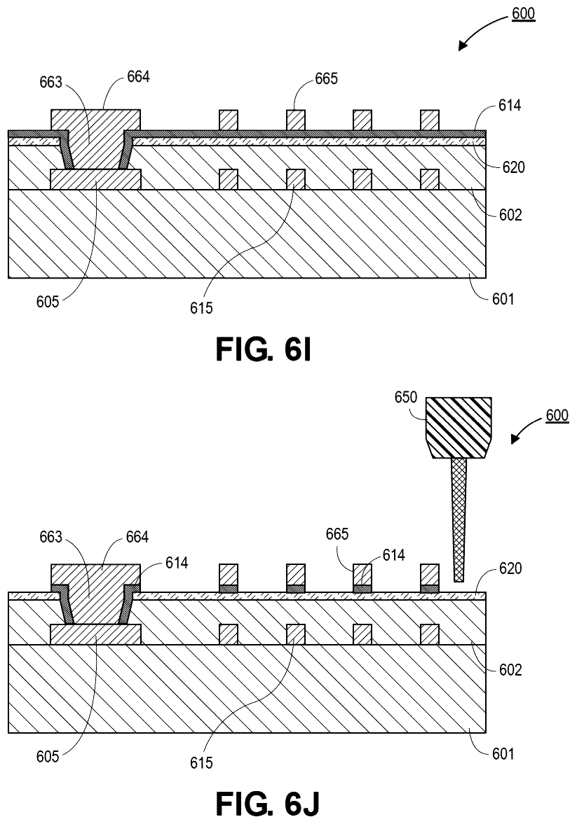

Referring now to FIGS. 6A-6J, a series of cross-sectional illustrations depicting a process for forming a portion of a package substrate 600 is shown, in accordance with an embodiment. In an embodiment, the package substrate 600 may include high density traces and pads. More particularly, pads that are stacked over each other may be electrically coupled together using micro-vias. The micro-vias may have a diameter that is approximately 5 μm or less in some embodiments. Additionally, the traces may be provided over a seed layer, and the seed layer may not undercut the traces. As such, a highly reliable package substrate 600 is provided.

Referring now to FIG. 6A, a cross-sectional illustration of a portion of a package substrate 600 is shown, in accordance with an embodiment. In an embodiment, the package substrate 600 may comprise a first layer 601 and a second layer 602. The first layer 601 and the second layer 602 may comprise a dielectric material, such as a buildup film or the like. In an embodiment, conductive features may be provided over the first layer 601 and covered by the second layer 602. For example, the conductive features may include one or more pads 605 and one or more traces 615. In the illustrated embodiment, the pads 605 and traces 615 are shown as being directly on the first layer 601. However, a seed layer (not shown) may be provided between the pads 605 and traces 615 and the underlying first layer 601. Further, in some embodiments a film (not shown) may be provided between the pads 605 and traces 615 and the first layer 601. The film may be similar to the films described in greater detail with respect to FIG. 6B.

Referring now to FIG. 6B, a cross-sectional illustration of the package substrate 600 after a film 620 is formed over the second layer 602 is shown, in accordance with an embodiment. The film 620 may be an inorganic film 620. For example, the film may be an oxide (e.g., comprising oxygen and silicon), a carbide, a nitride, an oxynitride, or an oxycarbide. The film 620 may be a reflective film 620. That is, the film 620 may reflect or otherwise not absorb electromagnetic radiation emitted by a laser in subsequent processing operations. In an embodiment, the film 620 may have a thickness that is less than approximately 5 μm, or less than approximately 3 μm. For example, the film 620 may have a thickness between approximately 100 nm and approximately 3 μm in some embodiments.

In an embodiment, the film 620 may be applied with any suitable thin film deposition process. In one embodiment, the film 620 may be applied with a chemical vapor deposition (CVD) process. In another embodiment, the film 620 may be applied with an atomic layer deposition (ALD) process. The film 620 may be applied as a blanket layer. That is, the film 620 may be applied over the entire top surface of the second layer 602.

Referring now to FIG. 6C, a cross-sectional illustration of the package substrate 600 after a resist layer 630 is applied over the film 620 is shown, in accordance with an embodiment. The resist layer 630 may be a photosensitive resist layer 630. That is, the resist layer 630 may be exposed and patterned using a photolithography process. The resist layer 630 may be used in order to pattern one or more openings in the film 620. Particularly, a resist layer 630 and photolithography may be necessary since the film 620 is reflective to laser light. As such, a mask is formed into the resist layer 630 and the underlying film 620 is patterned with an etching process. The formation of holes in the film 620 allows for the formation of micro-vias that have a diameter that is smaller than the spot size of the laser used to form the micro-via openings.

Referring now to FIG. 6D, a cross-sectional illustration of the package substrate 600 after the resist layer 630 is exposed and developed is shown, in accordance with an embodiment. In an embodiment, the resist layer 630 may be patterned in order to form an opening 631. The opening 631 may be positioned over the pad 605. In some embodiments, the diameter of the opening 631 may be smaller than a diameter of the pad 605. More particularly, the opening 631 may have a diameter that is smaller than the spot size of the laser that will subsequently be used to form the via opening in the second layer 602.

Referring now to FIG. 6E, a cross-sectional illustration of the package substrate 600 after the opening 631 is transferred into the film 620 is shown, in accordance with an embodiment. In an embodiment, the film 620 may be patterned with an etching process, such as a wet etching process. The opening 631 may expose a top surface of the second layer 602 above the pad 605.

Referring now to FIG. 6F, a cross-sectional illustration of the package substrate 600 after the resist layer 630 is removed is shown, in accordance with an embodiment. In an embodiment, the resist layer 630 may be removed with a resist stripping process, an etching process, or the like. As shown, removal of the resist layer 630 results in the exposure of the top surface of the film 620.

Referring now to FIG. 6G, a cross-sectional illustration of the package substrate 600 after a via opening 625 is formed is shown, in accordance with an embodiment. In an embodiment, the via opening 625 may be formed with a laser ablation process using a laser 650. The laser ablation process may use a laser 650 that has a spot size 651 with a diameter that is wider than a diameter of the opening 631. As such, portions of the laser emission are blocked (and reflected) by the film 620 adjacent to the opening 631. Accordingly, the via opening 625 may have a diameter that substantially matches the diameter of the opening 631. As shown in the illustrated embodiment, the via opening 625 may have tapered sidewalls, as is common with laser ablation processes. That is, a top of the via opening 625 may be wider than a bottom of the via opening 625. In an embodiment, the via opening 625 may have a diameter that is approximately 10 μm or less, approximately 5 μm or less, or approximately 3 μm or less. The via opening 625 exposes the underlying pad 605.

Referring now to FIG. 6H, a cross-sectional illustration of the package substrate 600 after a seed layer 614 is formed is shown, in accordance with an embodiment. In an embodiment, the seed layer 614 may be a blanket deposited layer. That is, the seed layer 614 may cover the top surfaces of the film 620. Further, the seed layer 614 may line the sidewalls of the via opening 625 and the sidewalls of the film 620. While not shown, the seed layer 614 may also cover the exposed top surface of the pad 605 in some embodiments.

The seed layer 614 may comprise any standard seed layer formulation. For example, the seed layer 614 may comprise titanium and copper in some embodiments. The seed layer 614 may have any suitable thickness. For example, the seed layer 614 may have a thickness that is less than approximately 1 μm, or less than approximately 500 nm. The seed layer 614 may comprise a layer of titanium and an overlying layer of copper in some embodiments. The seed layer 614 may be applied with any suitable deposition process, such as physical vapor deposition (PVD), CVD, or ALD.

Referring now to FIG. 6I, a cross-sectional illustration of the package substrate 600 after pads 664 and traces 665 are formed over the seed layer 614 is shown, in accordance with an embodiment. In an embodiment, the pads 664 and traces 665 may be formed with any suitable metal deposition and patterning process. In one embodiment, the conductive features may be formed with an SAP process. For example, a resist layer may be deposited and patterned to form openings for the pad 664 and the traces 665, and the pad 664 and traces 665 may be plated up from the seed layer 614.

The pad 664 may be electrically coupled to the underlying pad 605 by a via 663. The via 663 may have a diameter that is approximately 5 μm or less, or approximately 3 μm or less. The traces 665 may be high density traces 665. For example, the traces 665 may have a L/S dimension of approximately 5 μm/5 μm or less, or of approximately 3 μm/3 μm or less.

Referring now to FIG. 6J, a cross-sectional illustration of the package substrate 600 after the seed layer 614 is removed is shown, in accordance with an embodiment. In an embodiment, the seed layer 614 may be removed by a laser 650. The laser 650 allows for anisotropic removal of the seed layer 614. As such, there is no undercutting of the seed layer 614 below the pad 664 or the traces 665. Further, the presence of the film 620 prevents the laser 650 from damaging the underlying second layer 602. This enables a smooth surface onto which the next layer can be applied and improves the reliability of the package substrate 600.

While shown as using a laser ablation process, it is to be appreciated that the seed layer 614 may be removed with any suitable anisotropic removal process. For example, in some embodiments a dry etch (e.g., plasma etch) of the seed layer 614 may be used. Similar to above, when an anisotropic process is used there is no undercut of the pad 664 or traces 665. When such a process is used, there should be good etch selectivity between the seed layer 614 and the film 620 in order to prevent damage to the film 620.

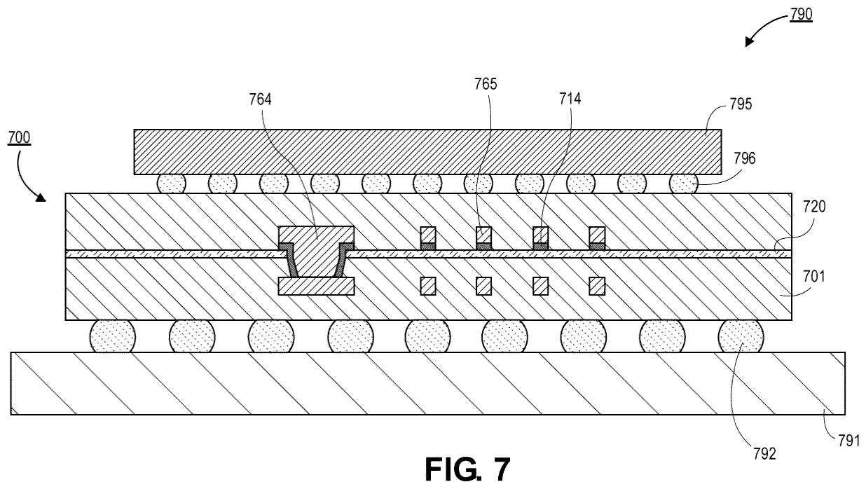

Referring now to FIG. 7, a cross-sectional illustration of a computing system 790 is shown, in accordance with an embodiment. In an embodiment, the computing system 790 may comprise a board 791, such as a printed circuit board (PCB). In an embodiment, a package substrate 700 may be coupled to the board 791 by interconnects 792. The interconnects 792 may comprise solder bumps, sockets, or the like.

In an embodiment, the package substrate 700 may comprise conductive features similar to those described in greater detail above. For example, pads 764 and traces 765 may be provided. The pads 764 and traces 765 may be provided over residual portions of a seed layer 714. The seed layer 714 may be provided over a film 720. For example, the film 720 may be an inorganic and reflective film. A film 720 may be provided between layers 701 of the package substrate 700.

In an embodiment, one or more dies 795 may be coupled to the package substrate 700 by interconnects 796. The interconnects 796 may be solder balls or any other suitable first level interconnect (FLI) architecture. The one or more dies 795 may comprise compute dies (e.g., central processing unit (CPU), graphics processing unit (GPU), XPU, system on a chip (SoC), a communication die, a memory device, or the like).

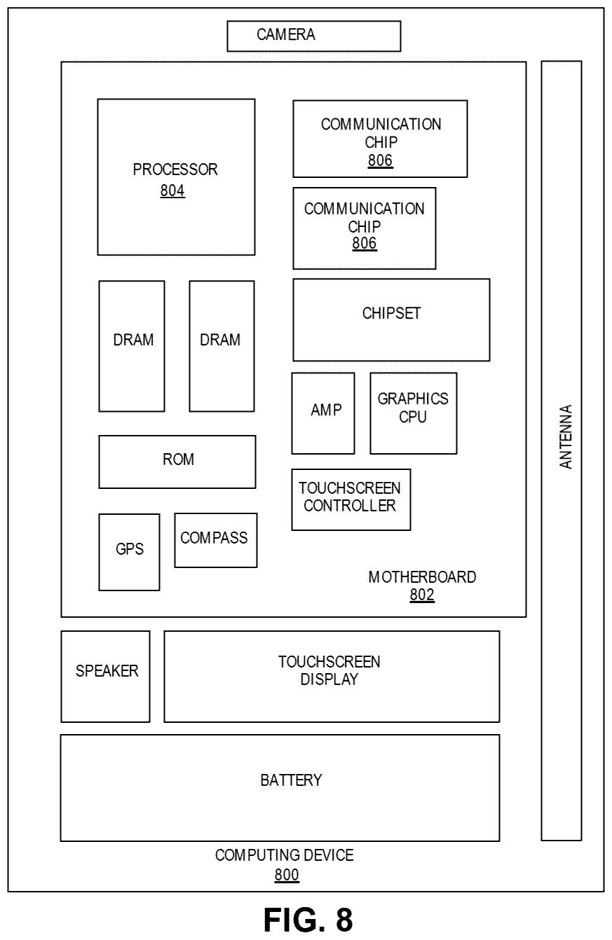

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package with a package substrate that comprises an inorganic reflective film between dielectric layers of the package substrate, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package with a package substrate that comprises an inorganic reflective film between dielectric layers of the package substrate, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a layer; a film over the layer, wherein the film is an inorganic material; a plurality of electrically conductive traces over the film; and a seed layer between the plurality of electrically conductive traces and the film, wherein edges of the seed layer are substantially aligned with edges of the plurality of electrically conductive traces.

Example 2: the package substrate of Example 1, wherein the film is up to approximately 3 μm thick.

Example 3: the package substrate of Example 2, wherein the film is between approximately 100 nm and approximately 1 μm thick.

Example 4: the package substrate of Examples 1-3, wherein the film comprises oxygen and silicon.

Example 5: the package substrate of Examples 1-4, wherein the film

comprises carbon.

Example 6: the package substrate of Examples 1-5, wherein widths of the plurality of electrically conductive traces are approximately 5 μm or less.

Example 7: the package substrate of Example 6, wherein a spacing between electrically conductive traces is approximately 5 μm or less.

Example 8: the package substrate of Examples 1-7, wherein the film is a reflective inorganic film.

Example 9: the package substrate of Examples 1-8, further comprising a via in the layer, wherein the via passes through the film.

Example 10: the package substrate of Example 9, wherein the via is lined by the seed layer.

Example 11: a package substrate, comprising: a first layer; a first pad on the first layer; a second layer over the first layer and the pad; a film over the second layer, wherein the film comprises an inorganic material; a second pad over the film; and a via through the film and the second layer to electrically couple the first pad to the second pad.

Example 12: the package substrate of Example 11, wherein the via has a width that is approximately 5 μm or less.

Example 13: the package substrate of Example 11 or Example 12, further comprising: a seed layer lining the via.

Example 14: the package substrate of Example 13, wherein the seed layer contacts a sidewall of the second layer, a sidewall of the film, and a top surface of the film.

Example 15: the package substrate of Examples 11-14, wherein the film has a thickness of approximately 3 μm or less.

Example 16: the package substrate of Examples 11-15, further comprising: a plurality of conductive traces over the film, wherein the plurality of traces have widths up to approximately 3 μm and a spacing up to approximately 3 μm.

Example 17: the package substrate of Examples 11-16, wherein the film comprises oxygen and silicon, or the film comprises carbon.

Example 18: a computing system, comprising: a board; a package substrate coupled to the board, wherein the package substrate comprises: a first layer; a first routing layer on the first layer; a second layer over the first layer; a film over the second layer, wherein the film comprises an inorganic material; and a second routing layer over the film; and a die coupled to the package substrate.

Example 19: the computing system of Example 18, wherein the film has a thickness up to approximately 3 μm.

Example 20: the computing system of Example 18 or Example 19, wherein the computing system is part of a personal computer, a server, a mobile device, a tablet, or an automobile.

What is claimed is:

1. A package substrate, comprising:
a layer;
a film over the layer, wherein the film is an inorganic material;
a plurality of electrically conductive traces over the film; and
a seed layer between the plurality of electrically conductive traces and the film, wherein edges of the seed layer are substantially aligned with edges of the plurality of electrically conductive traces.

2. The package substrate of claim 1, wherein the film is up to approximately 3 μm thick.

3. The package substrate of claim 2, wherein the film is between approximately 100 nm and approximately 1 μm thick.

4. The package substrate of claim 1, wherein the film comprises oxygen and silicon.

5. The package substrate of claim 1, wherein the film comprises carbon.

6. The package substrate of claim 1, wherein widths of the plurality of electrically conductive traces are approximately 5 μm or less.

7. The package substrate of claim 6, wherein a spacing between electrically conductive traces is approximately 5 μm or less.

8. The package substrate of claim 1, wherein the film is a reflective inorganic film.

9. The package substrate of claim 1, further comprising a via in the layer, wherein the via passes through the film.

10. The package substrate of claim 9, wherein the via is lined by the seed layer.

11. A package substrate, comprising:
a first layer;
a first pad on the first layer;
a second layer over the first layer and the pad;
a film over the second layer, wherein the film comprises an inorganic material;
a second pad over the film; and
a via through the film and the second layer to electrically couple the first pad to the second pad.

12. The package substrate of claim 11, wherein the via has a width that is approximately 5 μm or less.

13. The package substrate of claim 11, further comprising:
a seed layer lining the via.

14. The package substrate of claim 13, wherein the seed layer contacts a sidewall of the second layer, a sidewall of the film, and a top surface of the film.

15. The package substrate of claim 11, wherein the film has a thickness of approximately 3 μm or less.

16. The package substrate of claim 11, further comprising:
a plurality of conductive traces over the film, wherein the plurality of traces have widths up to approximately 3 μm and a spacing up to approximately 3 μm.

17. The package substrate of claim 11, wherein the film comprises oxygen and silicon, or the film comprises carbon.

18. A computing system, comprising:
a board;
a package substrate coupled to the board, wherein the package substrate comprises:
a first layer;
a first routing layer on the first layer;
a second layer over the first layer,
a film over the second layer, wherein the film comprises an inorganic material; and
a second routing layer over the film; and
a die coupled to the package substrate.

19. The computing system of claim 18, wherein the film has a thickness up to approximately 3 μm.

20. The computing system of claim 18, wherein the computing system is part of a personal computer, a server, a mobile device, a tablet, or an automobile.
